(19) United States
(12) Patent Application Publication
(10) Pub. No.: US 2025/0220976 A1
(43) Pub. Date: Jul. 3, 2025

(54) OXIDE SEMICONDUCTOR FILM, THIN FILM TRANSISTOR, SPUTTERING TARGET, AND OXIDE SINTERED BODY

(71) Applicants: Kabushiki Kaisha Kobe Seiko Sho (Kobe Steel, Ltd.), Kobe-shi (JP); KOBELCO RESEARCH INSTITUTE, INC., Kobe-shi (JP)

(72) Inventors: Mototaka OCHI, Kobe-shi (JP); Yumi TERAMAE, Osaka-shi (JP); Kohei NISHIYAMA, Kobe-shi (JP); Koichi MIYATA, Takasago-shi (JP)

(73) Assignees: Kabushiki Kaisha Kobe Seiko Sho (Kobe Steel, Ltd.), Kobe-shi (JP); KOBELCO RESEARCH INSTITUTE, INC., Kobe-shi (JP)

(21) Appl. No.: 18/848,704

(22) PCT Filed: Mar. 23, 2023
(86) PCT No.: PCT/JP2023/011638

§ 371 Date: Sep. 19, 2024

(30) Foreign Application Priority Data
Apr. 15, 2022 (JP) 2022-067933
Mar. 7, 2023 (JP) 2023-035101

(51) Int. Cl. H10D 30/67; H01L 21/02; H10D 30/01; H10D 62/60

(52) U.S. Cl. CPC H10D 30/6756; H10D 30/0314; H10D 30/6704; H10D 30/6729; H10D 30/6731; H10D 62/60; H01L 21/02631

(57) ABSTRACT

It is an object of the present invention to provide an oxide semiconductor film which enables improving both the carrier mobility and the stability with respect to environmental temperature of a thin film transistor. The oxide semiconductor film according to the one embodiment of the present invention contains, as metal elements: In and Zn; and an element X, being either of La and Nd, wherein contents of the In, the Zn, and the element X in total metal elements are: In: greater than or equal to 30 atm % and less than or equal to 90 atm %; Zn: greater than or equal to 9 atm % and less than or equal to 70 atm %; and X: greater than or equal to 0.0001 atm % and less than or equal to 2 atm %.

### TECHNICAL FIELD

The present invention relates to an oxide semiconductor film, a thin film transistor, a sputtering target, and an oxide sintered body.

### BACKGROUND ART

Thin film transistors (TFTs) are becoming more common as active elements for use in flat panel displays such as organic EL (organic electro-luminescence) devices. As these thin film transistors, a top gate type (staggered type) and a bottom gate type (reverse staggered type) are well known.

These thin film transistors are required to have high carrier mobility, as well as stability that is not dependent upon environmental temperature. In particular, in recent years, thin film transistors have sometimes been used in automotive displays and the like; thus, there has come to be a need for stability in environments that are harsher than conventional.

As semiconductor films which constitute these thin film transistors, amorphous oxide semiconductor films are used. Amorphous oxide semiconductors enable enhancing the carrier mobility compared to that of general-use amorphous silicon. Furthermore, amorphous semiconductors have a large optical band gap and enable film forming at low temperatures. Thus, amorphous oxide semiconductors are expected to be applied to, for example: next-generation displays for which large size, high resolution, and high-speed driving are demanded; substrates made of resin having low heat resistance; and the like (see Patent Documents 1, 2).

### PRIOR ART DOCUMENTS

### Patent Documents

Patent Document 1: Japanese Unexamined Patent Application, Publication No. 2010-219538
Patent Document 2: PCT International Publication No. 2009/81885

### SUMMARY OF THE INVENTION

### Problems to be Solved by the Invention

Patent Document 1 discloses an In—Ga—Zn—O (IGZO) amorphous oxide semiconductor consisting of In, Ga, Zn, and O. However, the carrier mobility of a TFT in which this IGZO amorphous oxide semiconductor is utilized is less than or equal to 10 cm²/Vs.

In contrast, Patent Document 2 discloses a high-mobility oxide which does not contain Ga. Patent Document 2 discloses that in an oxide consisting of In, Zn, and X, in a case in which X=Zr, Hf, Ge, Si, Ti, Mn, W, Mo, V, Cu, Ni, Co, Fe, Cr, or Nb, when an added amount of X is such that [0.01<X/(In+Zn+X)<0.2], or in a case in which X=Al, B, Sc, Y, La, Ce, Pr, Nd, Sm, Eu, Gd, Tb, Dy, Ho, Er, Tm, Yb, or Lu, when the added amount of X is such that [0.02<X/(In+Zn+X)<0.3], high mobility is obtained. However, Patent Document 2 does not disclose the stability with respect to environmental temperature. Furthermore, in Patent Document 2, X is defined in a broad range and even within this range, there are cases of the mobility being low, the heat resistance and/or the like being insufficient, and the like; thus, it is difficult to deem that an appropriate constitution has been investigated.

The present invention was made in view of the foregoing circumstances, and an object of the present invention is to provide an oxide semiconductor film which enables enhancing, in a thin film transistor, both the carrier mobility and the stability with respect to environmental temperature.

### Means for Solving the Problems

An oxide semiconductor film according to one aspect of the present invention is an oxide semiconductor film for use in a thin film transistor, the oxide semiconductor film containing, as metal elements: In and Zn; and an element X, being either of La and Nd, wherein contents of the In, the Zn, and the element X in total metal elements are: In: greater than or equal to 30 atm % and less than or equal to 90 atm %; Zn: greater than or equal to 9 atm % and less than or equal to 70 atm %; and X: greater than or equal to 0.0001 atm % and less than or equal to 2 atm %.

### Effects of the Invention

The oxide semiconductor film of the one aspect of the present invention enables enhancing, in a thin film transistor, both the carrier mobility and the stability with respect to environmental temperature.

### BRIEF DESCRIPTION OF THE DRAWINGS

FIG. 1 is a schematic cross sectional view illustrating a top gate-type thin film transistor according to one embodiment of the present invention.

FIG. 2 is a flow chart illustrating a method for producing an oxide sintered body according to one embodiment of the present invention.

FIG. 3 is a flow chart illustrating a method for producing a sputtering target according to one embodiment of the present invention.

FIG. 4 is a graph illustrating measurement results of static characteristics (Id-Vg characteristics) of a top gate-type thin film transistor of No. 4.

FIG. 5 is a graph illustrating measurement results of static characteristics (Id-Vg characteristics) of a top gate-type thin film transistor of No. 13.

FIG. 6 is a backscattered electron image of an oxide sintered body of No. 14.

FIG. 7 shows results of an X-ray diffraction spectrum analysis of the oxide sintered body of No. 14.

FIG. 8 is a backscattered electron image of an oxide sintered body of No. 15.

FIG. 9 is a partial enlarged view of the backscattered electron image in FIG. 8.

FIG. 10 shows results of an X-ray diffraction spectrum analysis of the oxide sintered body of No. 15.

FIG. 11 is a backscattered electron image of an oxide sintered body of No. 16.

FIG. 12 shows results of an X-ray diffraction spectrum analysis of the oxide sintered body of No. 16.

FIG. 13 is a backscattered electron image of an oxide sintered body of No. 17.

FIG. 14 shows results of an X-ray diffraction spectrum analysis of the oxide sintered body of No. 17.

FIG. 15 is a graph illustrating a relationship between relative density and sintering temperature in an oxide sintered body.

FIG. 16 is a backscattered electron image of an oxide sintered body of No. 18.

FIG. 17 shows results of an X-ray diffraction spectrum analysis of the oxide sintered body of No. 18.

### DESCRIPTION OF EMBODIMENTS

### Description of Embodiments of Present Invention

First, embodiments of the present invention are listed and described.

An oxide semiconductor film according to one embodiment of the present invention is an oxide semiconductor film for use in a thin film transistor, the oxide semiconductor film containing, as metal elements: In and Zn; and an element X, being either of La and Nd, wherein contents of the In, the Zn, and the element X in total metal elements are: In: greater than or equal to 30 atm % and less than or equal to 90 atm %; Zn: greater than or equal to 9 atm % and less than or equal to 70 atm %; and X: greater than or equal to 0.0001 atm % and less than or equal to 2 atm %.

The above-described Patent Document 2 discloses that in a field effect transistor comprising a semiconductor layer comprising a composite oxide which comprises In, Zn, and one or more elements X selected from the group consisting of Zr, Hf, Ge, Si, Ti, Mn, W, Mo, V, Cu, Ni, Co, Fe, Cr, Nb, Al, B, Sc, Y and lanthanoids (La, Ce, Pr, Nd, Sm, Eu, Gd, Tb, Dy, Ho, Er, Tm, Yb and Lu), due to controlling the amount of addition of X to be less than or equal to a certain value, a decrease in mobility can be inhibited, and thermal stability, heat resistance, and the like can be improved. On the other hand, upon thorough investigation by the present inventors, knowledge was gained that depending on the type of X, there is a difference in environmental temperature resistance. Moreover, the present inventors found that the elements X which enable achieving both an improvement in carrier mobility and environmental temperature resistance are La and Nd. According to the knowledge gained by the present inventors, due, in the oxide semiconductor film, to the In and the Zn, as well as the element X, being either of La and Nd, being controlled to fall within the above-described ranges, both the carrier mobility and the stability with respect to environmental temperature of a thin film transistor can be enhanced.

The contents of the In and the Zn in the total metal elements are preferably In: greater than or equal to 55 atm % and less than or equal to 80 atm %, and Zn: greater than or equal to 20 atm % and less than or equal to 50 atm %. When the contents of the In and the Zn in the total metal elements thus fall within the above ranges, the carrier mobility, optimization of threshold voltage, and the like of a thin film transistor can be promoted.

It is preferred that as a metal element, an element Y, being either of Sn and Ge, is further contained, and that a content of the element Y in the total metal elements is Y: greater than or equal to 0.0001 atm % and less than or equal to 4 atm %. When, as a metal element, the element Y, being either of Sn and Ge, is further contained, and the content of the element Y in the total metal elements falls within the above range, an optical band gap can be enlarged. As a result, characteristics as a high-mobility material having high carrier density can be stabilized, and the optimization of the threshold voltage, the stability with respect to environmental temperature, and the like of the thin film transistor can be improved.

The content of the element Y in the total metal elements is preferably Y: greater than 1 atm % and less than or equal to 2 atm %. When the content of the element Y in the total metal elements thus falls within the above range, the optimization of the threshold voltage, the stability with respect to environmental temperature, and the like of the thin film transistor can be further improved.

A thin film transistor of another embodiment of the present invention includes the oxide semiconductor thin film of the one embodiment of the present invention.

Due to including the oxide semiconductor film, the thin film transistor has high carrier mobility, and is superior in stability with respect to environmental temperature.

A sputtering target according to still another embodiment of the present invention is a sputtering target for forming an oxide semiconductor film for use in a thin film transistor, the sputtering target containing, as metal elements: In and Zn; and an element X, being either of La and Nd, wherein contents of the In, the Zn, and the element X in total metal elements are: In: greater than or equal to 30 atm % and less than or equal to 90 atm %; Zn: greater than or equal to 9 atm % and less than or equal to 70 atm %; and X: greater than or equal to 0.0001 atm % and less than or equal to 2 atm %.

Furthermore, a sputtering target according to yet another embodiment of the present invention is a sputtering target for forming an oxide semiconductor film for use in a thin film transistor, the sputtering target containing, as metal elements: In and Zn; and an element X, being either of La and Nd, wherein contents of the In and the Zn in total metal elements are: In: greater than or equal to 30 atm % and less than or equal to 90 atm %; and Zn: greater than or equal to 9 atm % and less than or equal to 70 atm %, the sputtering target contains an In oxide crystal phase, a ZnIn oxide crystal phase, and an XIn oxide crystal phase, and a constitution of the ZnIn oxide crystal phase is Zn₃In₂O₆ and/or Zn₄In₂O₇.

The sputtering target enables producing an oxide semiconductor film which enables enhancing, in a thin film transistor, both the carrier mobility and the stability with respect to environmental temperature.

An oxide sintered body according to a further embodiment of the present invention is an oxide sintered body for forming an oxide semiconductor film for use in a thin film transistor, the oxide sintered body containing, as metal elements: In and Zn; and an element X, being either of La and Nd, wherein contents of the In and the Zn in total metal elements are: In: greater than or equal to 30 atm % and less than or equal to 90 atm %; and Zn: greater than or equal to 9 atm % and less than or equal to 70 atm %, the oxide sintered body contains an In oxide crystal phase, a ZnIn oxide crystal phase, and an XIn oxide crystal phase, and a constitution of the ZnIn oxide crystal phase is Zn₃In₂O₆ and/or Zn₄In₂O₇.

The oxide sintered body enables producing an oxide semiconductor film which enables enhancing, in a thin film transistor, both the carrier mobility and the stability with respect to environmental temperature.

### Details of Embodiments of Present Invention

Hereinafter, embodiments of the present invention are described in detail with reference to a drawing or drawings as appropriate. It is to be noted that with regard to numerical values described in the present specification, it is possible to adopt only one of an upper limit value and a lower limit value described, or to combine both an upper limit value and a lower limit value ad libitum. In the present specification, all numerical value ranges from upper limit values to lower limit values which may be combined are described as suitable ranges.

### [Oxide Semiconductor Film]

The oxide semiconductor film is used in a thin film transistor. The oxide semiconductor film contains, as metal elements: In (indium) and Zn (zinc); and an element X, being either of La (lanthanum) and Nd (neodymium). In the oxide semiconductor film, contents of the In, the Zn, and the element X in total metal elements are: In: greater than or equal to 30 atm % and less than or equal to 90 atm %; Zn: greater than or equal to 9 atm % and less than or equal to 70 atm %; and X: greater than or equal to 0.0001 atm % and less than or equal to 2 atm %.

The oxide semiconductor film may be used in a thin film transistor of either a top gate type or a bottom gate type, and can be suitably used in a top gate-type thin film transistor including, on one side of a substrate, the oxide semiconductor film, a gate-insulating film, and a gate electrode, in this order. More specifically, the oxide semiconductor film is laminated directly on the substrate, or indirectly on the substrate via a buffer layer or the like. Furthermore, the gate electrode is disposed on the oxide semiconductor film via the gate-insulating film. Moreover, a conductive region (S/D region) is provided on the oxide semiconductor film, and a protective film and source/drain electrodes are disposed on this S/D region.

### In

In is an element that contributes to electrical conductivity. As the content of In increases, the electrical conductivity of the oxide semiconductor film improves, and the carrier density and the carrier mobility improve. The lower limit of the content of In in the total metal elements is 30 atm % as described above, and is preferably 50 atm %, and more preferably 55 atm %. On the other hand, the upper limit of the content of In in the total metal elements is 90 atm % as described above, and is preferably 80 atm %, and more preferably 78 atm %. When the content of In is less than the lower limit, it may not be possible to sufficiently obtain the carrier mobility. Conversely, when the content of In is greater than the upper limit, device characteristics may become unstable and the threshold voltage may indicate a large negative value, and/or the heat resistance may be insufficient.

### Zn

Zn is an element that affects processing characteristics of the oxide semiconductor film. The lower limit of the content of Zn in the total metal elements is 9 atm % as described above, and is preferably 10 atm %, and more preferably 20 atm %. On the other hand, the upper limit of the content of Zn in the total metal elements is 70 atm % as described above, and is preferably 65 atm %, and more preferably 50 atm %. When the content of Zn is less than the lower limit, the content of In may become excessively great on a relative basis, whereby the device characteristics may become unstable and the threshold voltage may indicate a large negative value, and/or the heat resistance may be insufficient. Conversely, when the content of Zn is greater than the upper limit, partial crystallization may occur, whereby it may be difficult to secure uniformity of the oxide semiconductor film.

### X

As described above, the oxide semiconductor film contains either of La and Nd as the element X. The present inventors have found that it is preferable to contain either of La and Nd as the element X for enhancing the stability with respect to environmental temperature. In particular, the present inventors have found that when either of La and Nd is contained at a proportion of less than or equal to 2 atm %, both an improvement in the carrier mobility and stability with respect to environmental temperature can be achieved. The lower limit of a content of X in the total metal elements is 0.0001 atm % as described above, and is preferably 0.1 atm %. On the other hand, the upper limit of the content of X in the total metal elements is 2 atm % as described above, and is preferably 1.6 atm %. When the content of X is less than the lower limit, it may not be possible to sufficiently obtain the stability with respect to environmental temperature. Conversely, when the content of X is greater than the upper limit, the carrier density may be insufficient, and it may be difficult to realize high mobility as a thin film transistor.

The oxide semiconductor film may contain, as the element X, only one of La and Nd, or may contain both La and Nd. In the case in which the oxide semiconductor film contains both La and Nd as the element X, each of La and Nd may be contained within the above-described range, or only one of La and Nd may be contained within the above-described range. Furthermore, in the case in which both La and Nd are contained as the element X, it is particularly preferred that a total content of La and Nd falls within the above-described range.

### Y

The oxide semiconductor film may further contain, in addition to In, Zn, and X, an element Y, being either of Sn (tin) and Ge (germanium), as a metal element. When the oxide semiconductor film contains the element Y, the optical band gap can be enlarged. As a result, characteristics as a high-mobility material having high carrier density can be stabilized, and the optimization of the threshold voltage, the stability with respect to environmental temperature, and the like of the thin film transistor can be improved. The lower limit of a content of Y in the total metal elements is preferably 0.0001 atm %, more preferably 0.1 atm %, and still more preferably 1 atm %. On the other hand, the upper limit of the content of Y in the total metal elements is preferably 4 atm %, and more preferably 2 atm %. When the content of Y is less than the lower limit, it may not be possible to sufficiently enlarge the optical band gap. Conversely, when the content of Y is greater than the upper limit, the carrier density may be insufficient, and it may be difficult to realize high mobility as the thin film transistor.

The oxide semiconductor film may contain, as the element Y, only one of Sn and Ge, or may contain both Sn and Ge. In the case in which the oxide semiconductor film contains both Sn and Ge as the element Y, each of Sn and Ge may be contained within the above-described range, or only one of Sn and Ge may be contained within the above-described range. Furthermore, in the case in which both Sn and Ge are contained as the element Y, it is particularly preferred that a total content of Sn and Ge falls within the above-described range.

In the oxide semiconductor film, elements aside from those described above are O (oxygen) and inevitable impurities. The inevitable impurities may be contained owing to, e.g., raw materials, materials, production equipment, and/or the like. Examples of these inevitable impurities include Al, Pb, Si, Fe, Ni, Ti, Mg, Cr, and Zr. A content of the inevitable impurities in the oxide semiconductor film is preferably less than or equal to 1% by mass per element, and more preferably less than or equal to 500 mass ppm. It is to be noted that the contents of the In, the Zn, the element X, and the element Y in the oxide semiconductor film may be proportions accounted for in total elements aside from O.

An average thickness of the oxide semiconductor film may be determined from conditions that allow a drain current to be turned off in a case of use as a switching element. The lower limit of the average thickness of the oxide semiconductor film is preferably 10 nm, and more preferably 15 nm. On the other hand, the upper limit is preferably 60 nm, and more preferably 50 nm. It is to be noted that the “average thickness” as referred to herein means an average value of thicknesses at 5 arbitrary points.

The oxide semiconductor film preferably has an amorphous structure, or an amorphous structure in which at least a part thereof is crystallized. In other words, the oxide which forms the oxide semiconductor film is preferably amorphous, or amorphous such that at least a part thereof is crystallized. Even in the case of having such a structure, the oxide semiconductor film enables sufficiently enhancing the carrier mobility compared to that of general-use amorphous silicon. Furthermore, when the oxide semiconductor film has such a structure, the optical band gap can be easily and reliably enlarged.

Due to controlling gas pressure to fall within a range of greater than or equal to 1 mTorr and less than or equal to 5 mTorr and performing a surface treatment by means of plasma and/or reducing gas after film formation, the oxide semiconductor film enables obtaining the above-described amorphous structure. It is to be noted that “amorphous” as referred to means that a clear diffraction peak derived from crystallization does not appear, and measurement can be performed by using an X-ray diffractometer or the like.

The upper limit of a sheet resistance of the oxide semiconductor film (a sheet resistance of the S/D region after the film formation and after performing the surface treatment) is preferably 1.0 kΩ/□, and more preferably 0.5 kΩ/□. In the thin film transistor, a region (the S/D region) from source/drain electrodes to a channel portion in the oxide semiconductor film is made conductive. When the sheet resistance after the surface treatment is less than or equal to the upper limit, the oxide semiconductor film enables easily and reliably realizing making the S/D region conductive. It is to be noted that sheet resistance of a typical IGZO oxide semiconductor film is often greater than 1.0 kΩ/□. In such a conventional oxide semiconductor film, when thermal processing is added in a step of producing a thin film transistor, a tendency for the sheet resistance to increase is significantly exhibited. This is because the oxide semiconductor film is typically made conductive by means of damage to the constituent elements. For example, in the case in which an amount of oxygen decreases due to the surface treatment and the oxide semiconductor film is made conductive, when oxygen is supplemented from, e.g., a peripheral insulating layer due to the thermal processing, there is a tendency for the damage to be recovered and for the conductivity to be lost. Here, as the sheet resistance, a value obtained by measurement using a four probe-type resistance measurement device can be employed.

### Advantages

The above-described Patent Document 2 discloses that in a field effect transistor comprising a semiconductor layer comprising a composite oxide which comprises In, Zn, and one or more elements X selected from the group consisting of Zr, Hf, Ge, Si, Ti, Mn, W, Mo, V, Cu, Ni, Co, Fe, Cr, Nb, Al, B, Sc, Y and lanthanoids (La, Ce, Pr, Nd, Sm, Eu, Gd, Tb, Dy, Ho, Er, Tm, Yb and Lu), due to controlling the amount of addition of X to be less than or equal to a certain value, a decrease in mobility can be inhibited, and thermal stability, heat resistance, and the like can be enhanced. On the other hand, upon thorough investigation by the present inventors, knowledge was gained that depending on the type of X, there is a difference in environmental temperature resistance. Moreover, the present inventors found that the elements X which enable achieving both an improvement in carrier mobility and environmental temperature resistance are La and Nd. According to the knowledge gained by the present inventors, due, in the oxide semiconductor film, to the In and the Zn, as well as the element X, being either of La and Nd, being controlled to fall within the above-described ranges, both the carrier mobility and the stability with respect to environmental temperature of a thin film transistor can be enhanced.

### Thin Film Transistor

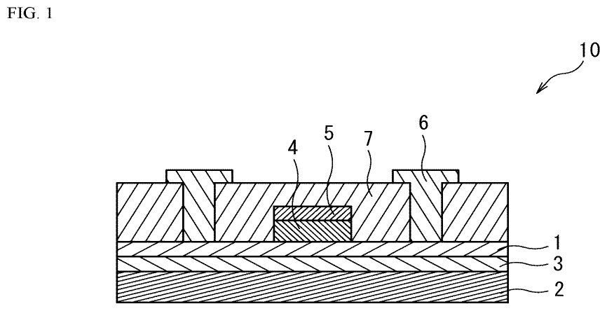

In FIG. 1, as an example of a thin film transistor including the above-described oxide semiconductor film, a top gate-type thin film transistor 10 (hereinafter, may be also referred to as simply “thin film transistor 10”) is shown. The thin film transistor 10 includes the oxide semiconductor film 1 having the above-described constitution. More specifically, the thin film transistor 10 includes: a substrate 2; a buffer layer 3 laminated on the substrate 2; the oxide semiconductor film 1 laminated on the buffer layer 3; a gate-insulating film 4 laminated on the oxide semiconductor film 1; a gate electrode 5 laminated on the gate-insulating film 4; source-drain electrodes 6 laminated on an S/D region, being a conductive region on the oxide semiconductor film 1; and a protective film 7. The thin film transistor 10 is provided on a display such as an organic EL display.

### Substrate

The substrate 2 is not particularly limited, and examples thereof include a glass substrate, a silicon substrate, and the like. Examples of a glass to be used in the glass substrate include a non-alkali glass, a high strain point glass, a soda-lime glass, and the like. Furthermore, as the substrate 2, a metal substrate such as a stainless steel thin film or a resin substrate such as a polyethylene terephthalate (PET) film may be used.

In light of processability, an average thickness of the substrate 2 is preferably greater than or equal to 0.001 mm and less than or equal to 10 mm. Furthermore, a size and shape of the substrate 2 may be set in accordance with a size and the like of the display.

### Buffer Layer

Examples of the buffer layer 3 may include a silicon oxide film. Film forming of the buffer layer 3 can be performed by means of a CVD (chemical vapor deposition) process, a PECVD (plasma-enhanced chemical vapor deposition) process, or the like. It is to be noted that the buffer layer 3 is provided in order to improve adhesiveness between the substrate 2 and the oxide semiconductor film 1, as well as to inhibit, e.g., diffusion of impurities from the substrate 2 into the oxide semiconductor film 1; thus, the buffer layer 3 is not a necessary layer in terms of operation, and can be omitted.

### Oxide Semiconductor Film

The oxide semiconductor film 1 is formed by means of, for example, a sputtering process using a sputtering target. The sputtering target for forming the oxide semiconductor film 1 is itself one embodiment of the present invention. Furthermore, the sputtering target can be formed using an oxide sintered body, which is itself one embodiment of the present invention. The oxide semiconductor film 1 is patterned by means of photolithography or the like after the film forming. Furthermore, directly after this patterning, a heat treatment (pre-annealing treatment) is preferably performed for film quality improvement. Hereinafter, the oxide sintered body and the sputtering target are described.

### Oxide Sintered Body

The oxide sintered body of the one embodiment of the present invention contains, as metal elements: In and Zn; and an element X, being either of La and Nd, wherein contents of the In, the Zn, and the element X in total metal elements are: In: greater than or equal to 30 atm % and less than or equal to 90 atm %; Zn: greater than or equal to 9 atm % and less than or equal to 70 atm %; and X: greater than or equal to 0.0001 atm % and less than or equal to 2 atm %. Furthermore, an oxide sintered body according to another embodiment of the present invention contains, as metal elements: In and Zn; and an element X, being either of La and Nd, wherein contents of the In and the Zn in total metal elements are: In: greater than or equal to 30 atm % and less than or equal to 90 atm %; and Zn: greater than or equal to 9 atm % and less than or equal to 70 atm %, the oxide sintered body contains an In oxide crystal phase, a ZnIn oxide crystal phase, and an XIn oxide crystal phase, and a constitution of the ZnIn oxide crystal phase is Zn₃In₂O₆ and/or Zn₄In₂O₇.

In the oxide sintered body, the ZnIn oxide crystal phase has, as principal components, a Zn₃In₂O₆ crystal phase and/or a Zn₄In₂O₇ crystal phase. The ZnIn oxide crystal phase may have both of the Zn₃In₂O₆ crystal phase and the Zn₄In₂O₇ crystal phase, or may have only one of these. Examples of a constitution of the In oxide crystal phase include In₂O₃. Examples of a constitution of the XIn oxide crystal phase include XInO₃. A lamellar pattern (a striped pattern or a spotted pattern) may be formed on the ZnIn oxide crystal phase.

The oxide sintered body may further contain, as a metal element, an element Y, being either of Sn and Ge. In the oxide sintered film, elements aside from those described above (elements other than In, Zn, X, and Y, which is contained as needed) are O and inevitable impurities. Contents of each element in the oxide sintered body can be the same as the ranges described in relation to the oxide semiconductor film 1.

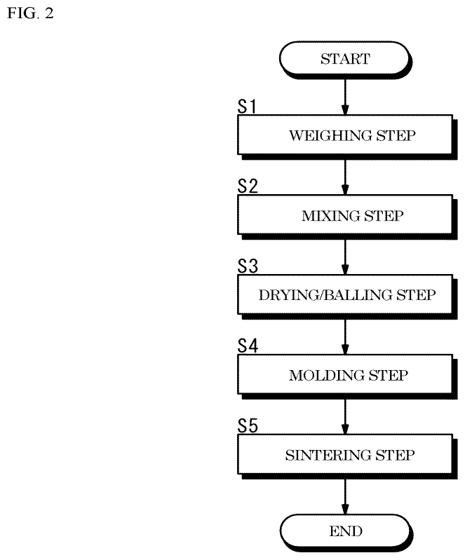

The oxide sintered body can be produced by the procedure described in FIG. 2. In other words, a method for producing the oxide sintered body includes: a step (a weighing step S1) of weighing raw material powders; a step (a mixing step S2) of mixing the raw material powders weighed in the weighing step S1; a step (a drying/balling step S3) of drying and balling a mixture obtained in the mixing step S2; a step (a molding step S4) of molding a balled powder obtained in the drying/balling step S3; and a step (a sintering step S5) of sintering a molded powder obtained in the molding step S4.

In the weighing step S1, the weighing is performed such that, for example, metal oxides of In₂O₃, ZnO, and X₂O₃ are the desired contents (atm %). In the mixing step S2, for example, the raw material powders weighed in the weighing step S1 and water, as well as a binder and a dispersant, which are added as needed, are charged into a nylon pot using zirconia balls as media, and mixing and pulverizing are performed using a ball mill to give a slurry. In the drying/balling step S3, the slurry obtained in the mixing step S2 is dried and a dried powder thus obtained is sieved to give a balled powder. It is to be noted that the drying/balling step S3 may be performed using a spray dryer. In the molding step S4, the balled powder obtained in the drying/balling step S3 is packed into a mold to give a molded powder. In the sintering step S5, the oxide sintered body is produced by using, for example, a normal pressure sintering process or a hot pressing process.

### Sputtering Target

A sputtering target according to one embodiment of the present invention contains, as metal elements: In and Zn; and an element X, being either of La and Nd, wherein contents of the In, the Zn, and the element X in total metal elements are: In: greater than or equal to 30 atm % and less than or equal to 90 atm %; Zn: greater than or equal to 9 atm % and less than or equal to 70 atm %; and X: greater than or equal to 0.0001 atm % and less than or equal to 2 atm %. Furthermore, the sputtering target according to another embodiment of the present invention contains, as metal elements: In and Zn; and an element X, being either of La and Nd, wherein contents of the In and the Zn in total metal elements are: In: greater than or equal to 30 atm % and less than or equal to 90 atm %; and Zn: greater than or equal to 9 atm % and less than or equal to 70 atm %, the sputtering target contains an In oxide crystal phase, a ZnIn oxide crystal phase, and an XIn oxide crystal phase, and a constitution of the ZnIn oxide crystal phase is Zn₃In₂O₆ and/or Zn₄In₂O₇.

The sputtering target may further contain, as a metal element, an element Y, being either of Sn and Ge. In the sputtering target, elements aside from those described above (elements other than In, Zn, X, and Y, which is contained as needed) are 0 and inevitable impurities. A constitution (crystal structure) of, and content of each element in, the sputtering target may be the same as those in the oxide sintered body.

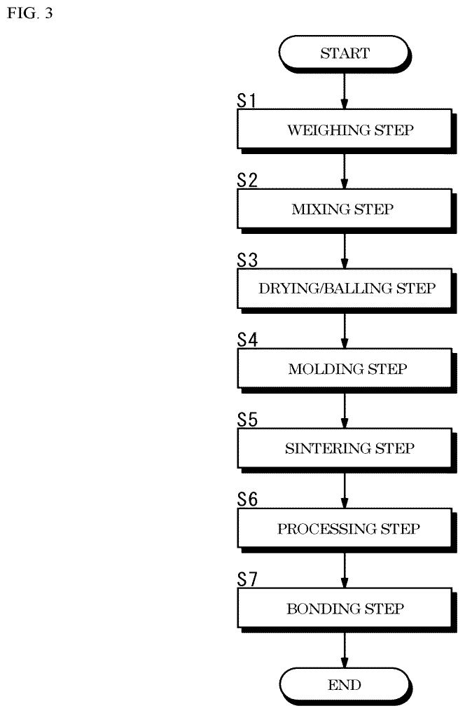

The sputtering target can be produced by a procedure described in FIG. 3. In other words, a method for producing the sputtering target includes: a step (a weighing step S1) of weighing raw material powders; a step (a mixing step S2) of mixing the raw material powders weighed in the weighing step S1; a step (a drying/balling step S3) of drying and balling a mixture obtained in the mixing step S2; a step (a molding step S4) of molding a balled powder obtained in the drying/balling step S3; a step (a sintering step S5) of sintering a molded powder obtained in the molding step S4; a step (a processing step S6) of processing the oxide sintered body obtained in the sintering step S5 into a desired size; and a step (a bonding step S7) of adhering the oxide sintered body (target) processed in the processing step S6 to a backing plate. The measuring step S1, the mixing step S2, the drying/balling step S3, the molding step S4, and the sintering step S5 in the method for producing a sputtering target may be performed by the procedures described above in the method for producing the oxide sintered body. In other words, the sputtering target may be formed by using the above-described oxide sintered body, and may have the same constitution as that of this oxide sintered body. In the processing step S6, the oxide sintered body is processed by, for example, machine processing. In the bonding step S7, for example, the target is bonded to a backing plate made of Cu.

### Gate Insulating Film

The gate insulating film 4 is formed on the oxide semiconductor film 1 after the above-described pre-annealing treatment. Examples of the gate insulating film 4 include: a silicon oxide film; a silicon nitride film; a silicon oxynitride film; a metal oxide film of Al₂O₃, Y₂O₃, or the like; and the like. The gate insulating film 4 can be formed by using a CVD procedure, a PECVD procedure, or the like. The gate insulating film 4 may be a monolayer body, or may be a multilayer body of two or more layers. In the case in which the gate insulating film 4 is the multilayer body of two or more layers, it is preferred that the first layer is a component which differs from that of the second layer and after.

The lower limit of an average thickness of the gate insulating film 4 is preferably 50 nm, and more preferably 100 nm. On the other hand, the upper limit of the average thickness of the gate insulating film 4 is preferably 300 nm, and more preferably 250 nm. When the average thickness is less than the lower limit, pressure resistance of the gate insulating film 4 may be insufficient. Conversely, when the average thickness is greater than the upper limit, capacitance of a capacitor formed between the gate electrode 5 and the oxide semiconductor film 1 may be insufficient, and the drain current may be insufficient. It is to be noted that in the case in which the gate insulating film 4 has multiple layers, the “average thickness of the gate insulating film” as referred to means the average thickness of the total gate insulating film.

### Gate Electrode

The gate electrode 5 has electric conductivity. The gate electrode 5 is, for example, formed after forming the gate insulating film 4, and after subjecting the oxide semiconductor film 1 to the heat treatment (the annealing treatment). The gate electrode 5 is not particularly limited, and metals having low electrical resistivity such as Al and Cu; metals having a high melting point such as Mo, Cr, or Ti, which have superior heat resistance; and/or an alloy of these can be preferably used.

The lower limit of an average thickness of the gate electrode 5 is preferably 50 nm, and more preferably 80 nm. When the average thickness is less than the lower limit, resistance of the gate electrode 5 may increase, whereby power consumption by the gate electrode 5 may increase. On the other hand, in light of processability and the like, the upper limit of the average thickness of the gate electrode 5 is preferably 500 nm, and more preferably 400 nm.

The gate insulating film 4 and the gate electrode 5 are patterned by means of photolithography or the like after forming of the gate electrode 5.

### Protective Film

The protective film 7 is formed after performing the surface treatment on the oxide semiconductor film 1, which is after the patterning of the gate insulating layer 4 and the gate electrode 5. This surface treatment is performed for the purpose of making conductive the S/D region of the oxide semiconductor film 1, and can be performed by, e.g., ion implantation, element diffusion, reduction by a reducing gas, a plasma treatment, or the like.

Examples of the protective film 7 include: a silicon oxide film; a silicon nitride film; a silicon oxynitride film; a metal oxide film of Al₂O₃, Y₂O₃, or the like; and the like. The protective 7 can be formed by using a CVD procedure, a PECVD procedure, or the like. A contact hole is formed in the protective film 7 by means of photolithography or the like after the film forming.

### Source/Drain Electrodes

The source/drain electrodes 6 have electric conductivity. The source/drain electrodes 6 cover a part of the protective film 7, and are packed into the contact hole. Due to being thus provided, the source/drain electrodes 6 electrically connect with the oxide semiconductor film 1 on both ends of a channel of the thin film transistor 10.

The source/drain electrodes 6 are not particularly limited, and metals having low electrical resistivity such as Al and Cu; metals having a high melting point such as Mo, Cr, or Ti, which have superior heat resistance; and/or an alloy of these can be preferably used.

The lower limit of an average thickness of the source/drain electrodes 6 is preferably 100 nm, and more preferably 150 nm. When the average thickness is less than the lower limit, resistance of the source/drain electrodes 6 may increase, whereby power consumption by the source/drain electrodes 6 may increase. On the other hand, the upper limit of the average thickness of the source/drain electrodes is preferably greater than the total thickness of the gate insulating film 4 and the gate electrode 5, and is, for example, preferably 1,000 m and more preferably 800 μm.

The source/drain electrodes 6 are patterned by means of photolithography or the like after the film forming.

### Characteristics of Thin Film Transistor

### Threshold Voltage Shift

The upper limit of a threshold voltage shift (an absolute value of a difference between a threshold voltage at 23° C. and a threshold voltage at 100° C.) of the thin film transistor 10 is preferably 3.5 V, more preferably 3.0 V, still more preferably 2.5 V, and particularly preferably 1.5 V When the threshold voltage shift is greater than the upper limit, the stability with respect to environmental temperature may become insufficient. It is to be noted that the lower limit of the threshold voltage shift of the thin film transistor 10 is not particularly limited, and can be 0 V. It is also to be noted that the “threshold voltage” as referred to means a gate voltage at which the drain current of the transistor is 10⁻⁹ A.

### Advantages

Due to including the oxide semiconductor film 1, the thin film transistor 10 has high carrier mobility, and is superior in stability with respect to environmental temperature.

The sputtering target is suitable for production of the oxide semiconductor film 1.

The oxide sintered body is suitable for production of the oxide semiconductor film 1.

### Other Embodiments

The above-described embodiments are not to be construed as limiting the configuration of the present invention. Therefore, constituent elements of each part of the above-described embodiment may be omitted, replaced, or added based on the description in the present specification and common technical knowledge, and such omission, replacement, and addition should be construed as falling within the scope of the present invention.

For example, specific structures of the thin film transistor are not limited to the structure shown in FIG. 1. For example, the protective layer may be a multilayer body on which multiple insulating layers are laminated. Furthermore, the thin film transistor may be a bottom gate type.

### EXAMPLES

Hereinafter, the present disclosure is further specifically described by way of Examples, but the present disclosure is not to be construed as being limited to the descriptions of the following Examples.

### Test Example 1

### Production of Top Gate-Type Thin Film Transistor

A top gate-type transistor having the structure shown in FIG. 1 was produced in accordance with the following procedure. First, by a CVD procedure under the following film forming conditions, an SiO₂ film having a thickness of 250 nm was formed, as a buffer layer, on a glass substrate (“Eagle 2000”, manufactured by Eagle) having a diameter of 4 inches and a thickness of 0.7 mm.
Film Forming Conditions for Buffer Layer
Carrier gas: mixed gas of SiH₄ and N₂O
Film forming power density: 0.96 W/cm²
Film forming temperature: 320° C.
Gas pressure during film forming: 133 Pa

Next, oxide semiconductor films, each having a thickness of 40 nm and being an In—Zn—X—O film or an In—Zn—X—Y—O film and containing metal elements in the proportion shown in Table 1, were formed by a spattering procedure. It is to be noted that analysis of contents of the metal elements in each oxide semiconductor film was conducted by separately forming an oxide semiconductor film having a thickness of 100 nm on a glass substrate in a manner similar to that described above. This analysis was conducted by ICP (inductively coupled plasma) emission spectroscopy using “CIROS Mark II,” manufactured by Rigaku Corporation.

Next, after forming the oxide semiconductor film, the oxide semiconductor film was patterned by photolithography and wet etching. It is to be noted that for all of the oxide semiconductor films of No. 1 to No. 13, there was no residue due to the wet etching, and it was confirmed that the etching was appropriately performed. After this patterning, a heat treatment (pre-annealing treatment) was performed on each oxide semiconductor film to improve the film quality. This pre-annealing treatment was performed in an ambient air atmosphere at 350° C. for 1 hour.

After this pre-annealing treatment, a gate insulating film was formed on the oxide semiconductor film by a CVD procedure under the following film forming conditions, and in order to further improve the film quality of each oxide semiconductor film, a heat treatment (annealing treatment) was performed in ambient air at 350° C. for 1 hour.
Film-Forming Conditions for Gate Insulating Film
Carrier gas: mixed gas of SiH₄ and N₂O
Film forming power density: 0.96 W/cm²
Film forming temperature: 270° C.
Gas pressure during film forming: 133 Pa

Next, a gate electrode consisting of an Mo metal film and having a thickness of 100 nm was formed, and was patterned by photolithography and wet etching. Furthermore, the gate insulating film was patterned by performing dry etching using this gate electrode as a mask. Subsequently, hydrogen plasma irradiation was performed for 15 sec on the surface of each oxide semiconductor film, and the S/D region of each oxide semiconductor film was made conductive.

After the plasma irradiation, a protective layer was formed by means of a CVD procedure under the following film forming conditions. Subsequently, a contact hole for probing for transistor characteristic evaluation was formed in the protective layer by means of photolithography and dry etching. Furthermore, source/drain electrodes were formed, patterning was performed by means of photolithography and wet etching, and finally, a heat treatment (post-annealing treatment) was performed at 250° C. in a nitrogen atmosphere for 30 min to give each thin film transistor.
Film-Forming Conditions for Protective Layer
Carrier gas: mixed gas of SiH₄ and N₂O
Film forming power density: 0.96 W/cm²
Film forming temperature: 250° C.
Gas pressure during film forming: 133 Pa

### Static Characteristic Evaluation

Drain current (Id)-gate voltage (Vg) characteristics (Id-Vg characteristics) of thin film transistors No. 1 to No. 13 were measured under the following conditions using a prober and a semiconductor parameter analyzer (“4200-SCS,” manufactured by Keithley Instruments).
Gate voltage: −30 V to 30 V (step: 0.25 V)
Source voltage: 0 V
Drain voltage: 10 V
Substrate temperature: room temperature (23° C.)

### Carrier Mobility

The carrier mobility μ_{FE} [cm²/Vs] was calculated from FE in the saturation region (Vg>Vd−Vth) of the static characteristics, which is shown in the following formula (1):

$${μ}_{FE} = \frac{\partial {I}_{d}}{\partial {V}_{g}} ( \frac{L}{{C}_{OX} \times W \times ( {V}_{g} - Vth )} ) \qquad ( 1 )$$

vherein Vg [V] denotes the gate voltage, Vth [V] denotes the threshold voltage, Id [A] denotes the drain current, L [m] denotes the channel length, W [m] denotes the channel width, and Cₒₓ[F] denotes the capacitance of the gate insulating film. The calculation results are shown in Table 1.

### Threshold Voltage

The threshold voltage [V] was defined as a gate voltage at which the drain current of a transistor was 10⁻⁹ A, and a value of the gate voltage was calculated from the static characteristics. The calculation results are shown in Table 1.

### S Value

For the S value [V/decade], an amount of change in gate voltage needed to increase the drain current by an order of magnitude was calculated from the static characteristics, and a minimum value thereof was taken. The calculation results are shown in Table 1

### Threshold Voltage Shift

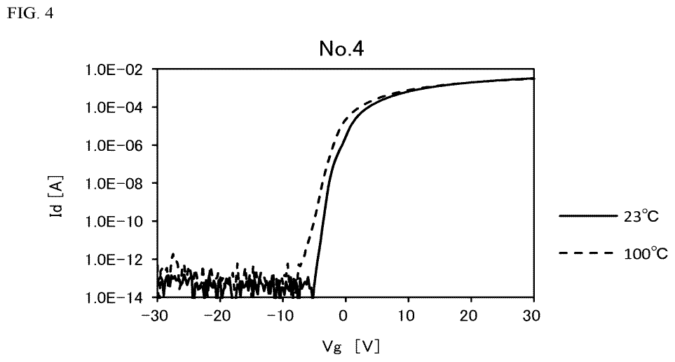

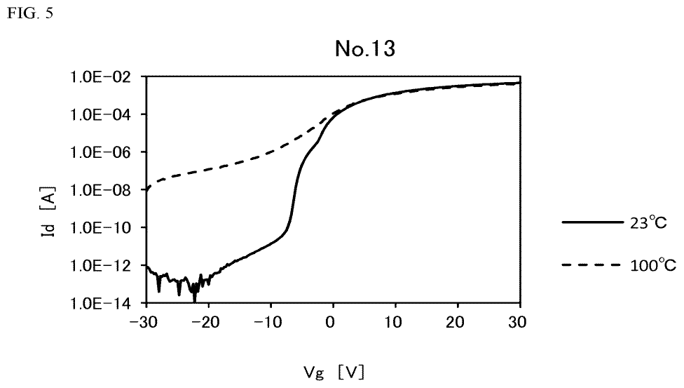

Static characteristics were measured under the same conditions as those described above, except that the substrate temperature was changed to 100° C. The absolute value of a difference between the threshold voltage at 23° C. and the threshold voltage at 100° C. was calculated, and was determined to be the threshold voltage shift [V]. The results are shown in Table 1. It is to be noted that the measurement results for the static characteristics of No. 4 are shown in FIG. 4, and the measurement results for the static characteristics of No. 13 are shown in FIG. 5. As shown in FIG. 5, in No. 13, at 100° C., the leak current became excessively great, whereby the current was greater than 10⁻⁹ A, at which the threshold voltage is calculated, whereby calculation of the threshold voltage failed; thus, it was not possible to measure the threshold voltage shift.

TABLE 1

| | | | | | | | | | | Threshold |
|---|---|---|---|---|---|---|---|---|---|---|
| | | | | | | | Carrier | Threshold | | voltage |
| | Element | | Content [atm %] | | | | mobility | voltage | S value | shift |
| No. | X | Y | In | Zn | X | Y | [cm²/Vs] | [V] | [V/decade] | [V] |
| 1 | Nd | — | 67.2 | 32.3 | 0.5 | — | 45 | 1 | 0.25 | 2.25 |
| 2 | Nd | — | 67.2 | 31.9 | 0.9 | — | 33 | 0.25 | 0.3 | 1.75 |
| 3 | Nd | — | 67 | 31.7 | 1.3 | — | 41.1 | −2.5 | 0.37 | 1.25 |
| 4 | Nd | — | 68.8 | 29.5 | 1.7 | — | 37.6 | −1.75 | 0.43 | 1.25 |
| 5 | Nd | — | 71.4 | 28.3 | 0.34 | — | 47.8 | −1.75 | 0.21 | 2.25 |
| 6 | Nd | Sn | 71.4 | 27 | 0.41 | 1.3 | 45.2 | −1 | 0.19 | 1 |
| 7 | Nd | Ge | 72.1 | 26.2 | 0.43 | 1.3 | 43.5 | −1 | 0.19 | 1 |
| 8 | La | — | 73.3 | 26.3 | 0.4 | — | 43.68 | −2.25 | 0.17 | 3.25 |
| 9 | Nd | — | 65.2 | 30.6 | 4.12 | — | 26 | 0.75 | 0.31 | 0 |
| 10 | Nd | — | 62.6 | 28 | 9.43 | — | 6 | 2.25 | 1.01 | 1.25 |
| 11 | Nd | — | 60.6 | 26.1 | 13.3 | — | 2.7 | 3.25 | 0.88 | 0.5 |
| 12 | Gd | — | 73.3 | 26.4 | 0.3 | — | 40.99 | −13 | 0.21 | 10.25 |
| 13 | Tb | — | 72.6 | 27 | 0.4 | — | 33.05 | −11.25 | 1.61 | — |

### Evaluation Results

As shown in Table 1 and FIGS. 4 and 5, each of No. 1 to No. 8 involved the oxide semiconductor film containing: In and Zn; and an element X, being either of La and Nd, wherein contents of In, Zn, and X in total metal elements are: In: greater than or equal to 30 atm % and less than or equal to 90 atm %; Zn: greater than or equal to 9 atm % and less than or equal to 70 atm %; and X: greater than or equal to 0.0001 atm % and less than or equal to 2 atm %; thus, the carrier mobility was greater than 30 cm²NVs, and the threshold voltage shift was less than or equal to 3.5 V This threshold voltage shift can be used as a marker of stability with respect to environmental temperature.

On the other hand, in No. 9 to No. 11, the content of X was greater than 2 atm %, whereby the carrier mobility was insufficient. Furthermore, No. 12 and No. 13 did not contain either of La and Nd as the element X, whereby the threshold voltage shift became greater and the stability with respect to environmental temperature was insufficient.

### Test Example 2

### Production of Oxide Sintered Body by Ordinary Pressure Sintering Procedure

Oxide sintered bodies No. 14 to No. 17 were produced using an ordinary sintering process based on the flow shown in FIG. 2. First, the metal oxides In₂O₃, ZnO, and Nd₂O₃ were weighed out such that contents of metal elements in each oxide sintered body to be obtained were as shown in FIG. 2. Subsequently, the raw material powders after weighing, water, and a binder and a dispersant were charged into a nylon pot using zirconia balls as media, and mixing and pulverizing were performed for 3 hrs using a ball mill. Next, a slurry thus obtained was dried with a hot plate and a mesh pass was performed using a sieve to give a balled powder of In₂O₃, ZnO, and Nd₂O₃. Next, this balled powder was packed into a mold and subjected to pressure at a molding pressure of 294 MPa for a holding time period of 3 min by means of cold isostatic pressing to give a molded product. Subsequently, this molded product was sintered at 1,500° C. for 2 hrs in ambient air to produce an oxide sintered body.

TABLE 2

| | Content [atm %] | | |
|---|---|---|---|
| No. | In | Zn | Nd |
| 14 | 66.7 | 33.3 | 0.0 |
| 15 | 66.2 | 33.1 | 0.7 |
| 16 | 65.4 | 32.7 | 1.9 |
| 17 | 64.0 | 32.0 | 4.0 |

### Crystal Structure

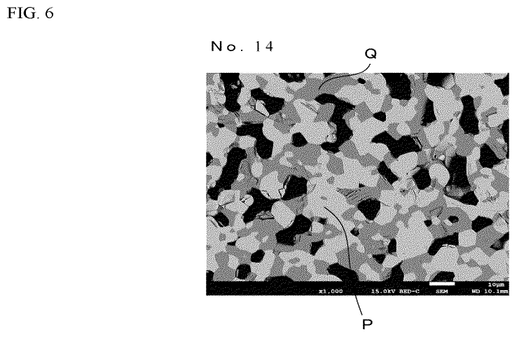

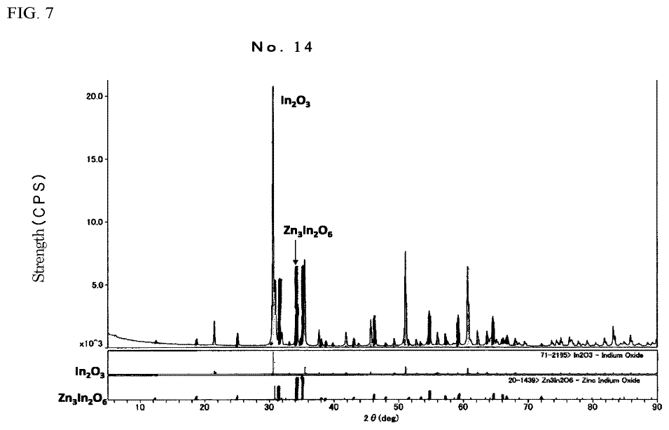

A SEM-EDX analysis and an X-ray diffraction spectrum analysis were performed on the oxide sintered bodies of No. 14 to No. 17. For No. 14, an SEM backscattered electron image is shown in FIG. 6, and the results of the X-ray diffraction spectrum analysis are shown in FIG. 7. As shown in FIG. 6 and FIG. 7, the oxide sintered body of No. 14 is composed of the two crystal phases of In₂O₃ and Zn₃In₂O₆.

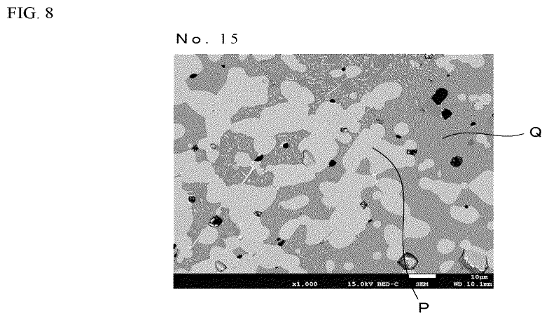

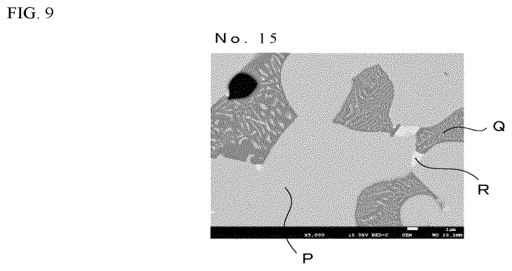

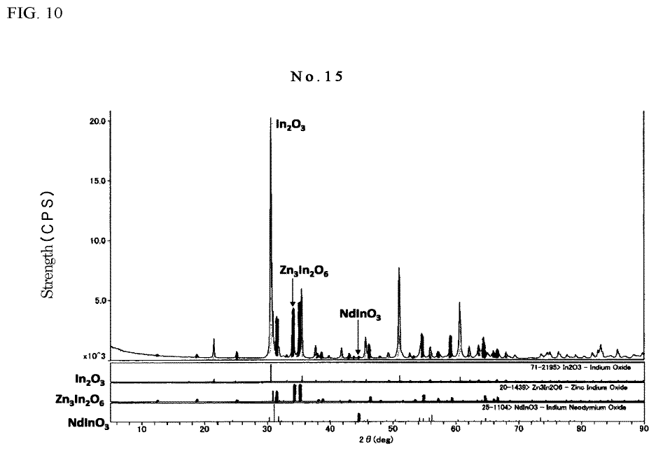

For No. 15, an SEM backscattered electron image is shown in FIG. 8, and the results of the X-ray diffraction spectrum analysis are shown in FIG. 10. Furthermore, a partial enlarged view of the SEM backscattered electron image of FIG. 8 is shown in FIG. 9. As shown in FIG. 8 to FIG. 10, the oxide sintered body of No. 15 contains 0.7 atm % Nd, thus having, in addition to In₂O₃ and Zn₃In₂O₆, an NdInO₃ crystal phase. Moreover, in No. 15, a lamellar structure was confirmed in the Zn₃In₂O₆ crystal phase.

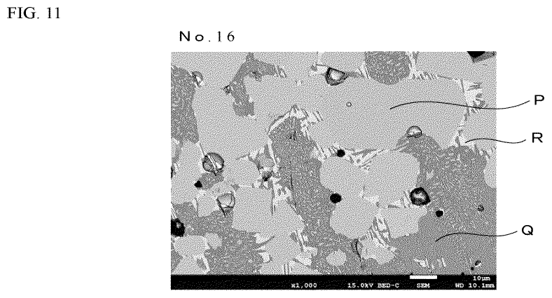

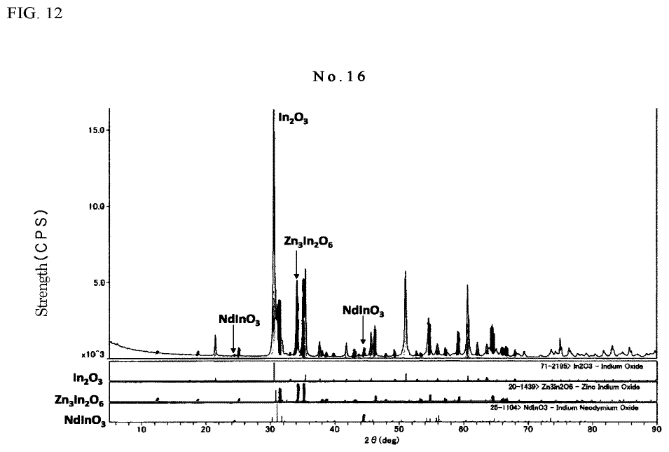

For No. 16, an SEM backscattered electron image is shown in FIG. 11, and the results of the X-ray diffraction spectrum analysis are shown in FIG. 12. As shown in FIG. 11 and FIG. 12, the oxide sintered body of No. 16 contains 1.9 atm % Nd, thus having, in addition to In₂O₃ and Zn₃In₂O₆, an NdInO₃ crystal phase. Furthermore, the proportion accounted for by the NdInO₃ crystal structure is greater in No. 16 than in No. 15. Moreover, in No. 16, a lamellar structure was confirmed in the Zn₃In₂O₆ crystal phase.

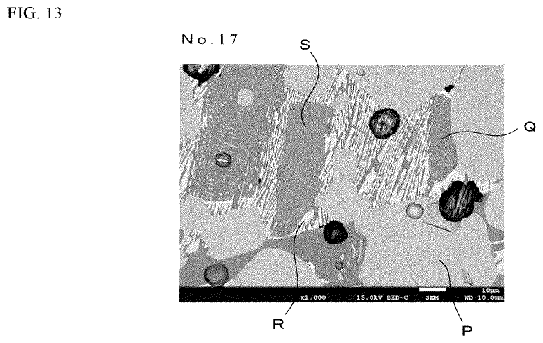

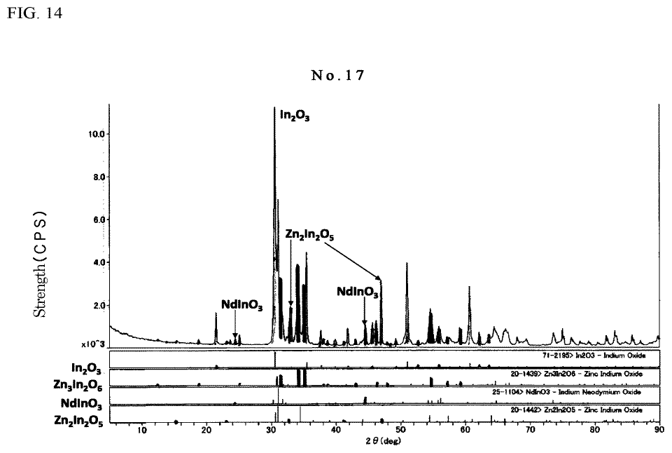

For No. 17, an SEM backscattered electron image is shown in FIG. 13, and the results of the X-ray diffraction spectrum analysis are shown in FIG. 14. As shown in FIG. 13 and FIG. 14, the oxide sintered body of No. 17 contains 4.0 atm % Nd; thus, in addition to In₂O₃, Zn₃In₂O₆, and NdInO₃ crystal phases, a fourth crystal phase (presumed to be Zn₂In₂O₅) consisting of an oxide in which proportions of Zn and In are equal is formed. Furthermore, in No. 17, a lamellar structure was confirmed in the Zn₃In₂O₆ crystal phase.

### Test Example 3

### Production of Oxide Sintered Body by Hot Pressing Process

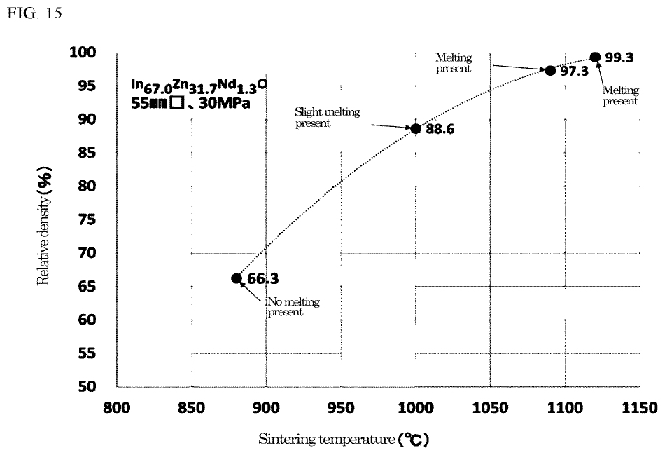

Oxide sintered bodies were produced using a hot pressing process based on the flow shown in FIG. 2. In Test Example 3, the metal oxides In₂O₃, ZnO, and Nd₂O₃ were weighed out such that contents of metal elements of each oxide sintered body to be obtained were as shown in FIG. 3. These raw material powders were mixed by the same procedure as that of Test Example 2, and then drying/balling and molding were performed. A balled powder after the molding was hot pressed at a sintering temperature of 880° C. to 1,120° C. for a sintering time period of 3 to 5 hours to produce each oxide sintered body. Relationships between the relative density and sintering temperatures of each oxide sintered body thus obtained are shown in FIG. 15.

TABLE 3

| | Content [atm %] | | |
|---|---|---|---|
| No. | In | Zn | Nd |
| 18 | 67.0 | 31.7 | 1.3 |

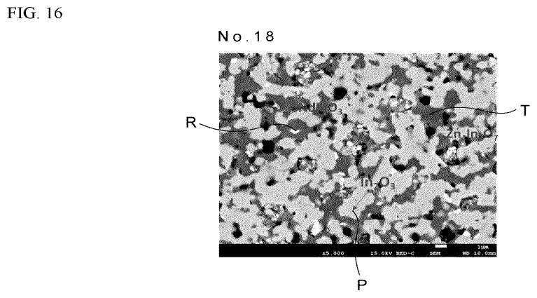

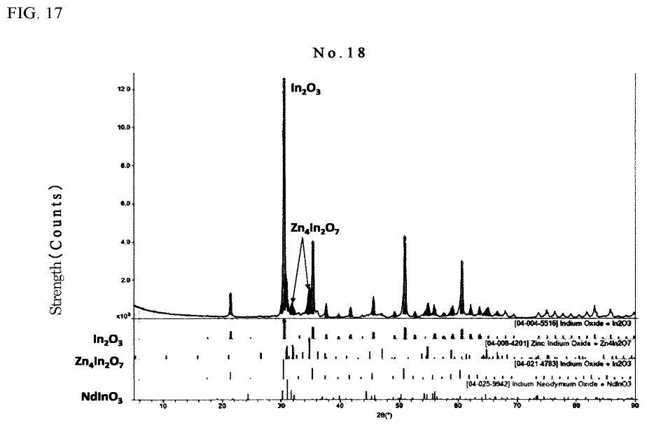

As shown in FIG. 15, the relative density of the oxide sintered body increases in accordance with increases in the sintering temperature. However, when the sintering temperature becomes too high, melting of the metal components increases; thus, it is difficult to control the components of the oxide sintered body to be obtained. From such a viewpoint, an oxide sintered body obtained by performing hot pressing at a sintering temperature of 1,000° C. was obtained as the oxide sintered body of No. 18. For No. 18, an SEM backscattered electron image is shown in FIG. 16, and the results of the X-ray diffraction spectrum analysis are shown in FIG. 17. As shown in FIG. 16 and FIG. 17, the oxide sintered body of No. 18 has In₂O₃, Zn₄In₂O₇, and NdInO₃ crystal phases.

### Production of Sputtering Target

Following the process shown in FIG. 3, a target was produced by subjecting the oxide sintered body of No. 18 to machine processing to a diameter of 50.8 mm and a thickness of 5 mm. The relative density of the target thus obtained was 90.3%. Subsequently, this target was bonded to a backing plate made of Cu by using In to produce a sputtering target (an InZnNd oxide sputtering target). Contents of the metal elements in this sputtering target (more specifically, the above-described target) were analyzed by ICP emission spectroscopy. The results are shown in Table 4.

TABLE 4
Content [atm %]

| In | Zn | Nd |
|---|---|---|
| 66.8 | 31.9 | 1.3 |

As shown in Table 4, it was confirmed that a sputtering target could be produced within ±1.0 atm % with respect to the charged composition. Furthermore, when an adhesion percentage of this sputtering target was measured by an ultrasonic inspection, the adhesion percentage was 100%. Moreover, warpage of the target was 0.1 mm, and positional deviation of the target was 0.2 mm.

### INDUSTRIAL APPLICABILITY

As described above, the oxide semiconductor film of the one embodiment of the present invention is suitable for improving both the carrier mobility and the stability with respect to environmental temperature of a thin film transistor.

### BRIEF DESCRIPTION OF THE DRAWINGS

1 oxide semiconductor film
2 substrate
3 buffer layer
4 gate insulating layer
5 gate electrode
6 source/drain electrodes
7 protective film
10 top gate-type thin film transistor
P In₂O₃ crystal phase
Q Zn₃In₂O₆ crystal phase
R NdInO₃ crystal phase
S fourth crystal phase
T Zn₄In₂O₇ crystal phase

1. An oxide semiconductor film for use in a thin film transistor, the oxide semiconductor film comprising, as metal elements:
In and Zn; and
an element X, being either of La and Nd,
wherein
contents of the In, the Zn, and the element X in total metal elements are:
In: greater than or equal to 30 atm % and less than or equal to 90 atm %;
Zn: greater than or equal to 9 atm % and less than or equal to 70 atm %; and
X: greater than or equal to 0.0001 atm % and less than or equal to 2 atm %.

2. The oxide semiconductor film according to claim 1, wherein the contents of the In and the Zn are:
In: greater than or equal to 55 atm % and less than or equal to 80 atm %; and
Zn: greater than or equal to 20 atm % and less than or equal to 50 atm %.

3. The oxide semiconductor film according to claim 1, further comprising, as a metal element, an element Y being either of Sn and Ge, wherein
a content of the element Y in the total metal elements is:
Y: greater than or equal to 0.0001 atm % and less than or equal to 4 atm %.

4. The oxide semiconductor film according to claim 3, wherein the content of the element Y in the total metal elements is:
Y: greater than 1 atm % and less than or equal to 2 atm %.

5. A thin film transistor comprising the oxide semiconductor film according to claim 1.

6. A thin film transistor comprising the oxide semiconductor film according to claim 2.

7. A thin film transistor comprising the oxide semiconductor film according to claim 3.

8. A thin film transistor comprising the oxide semiconductor film according to claim 4.

9. A sputtering target for forming an oxide semiconductor film for use in a thin film transistor, the sputtering target comprising, as metal elements:
In and Zn; and
an element X, being either of La and Nd,
wherein
contents of the In, the Zn, and the element X in total metal elements are:
In: greater than or equal to 30 atm % and less than or equal to 90 atm %;
Zn: greater than or equal to 9 atm % and less than or equal to 70 atm %; and
X: greater than or equal to 0.0001 atm % and less than or equal to 2 atm %.

10. A sputtering target for forming an oxide semiconductor film for use in a thin film transistor, the sputtering target comprising, as metal elements:
In and Zn; and
an element X, being either of La and Nd,
wherein
contents of the In and the Zn in total metal elements are:
In: greater than or equal to 30 atm % and less than or equal to 90 atm %; and
Zn: greater than or equal to 9 atm % and less than or equal to 70 atm %,
the sputtering target comprises an In oxide crystal phase, a ZnIn oxide crystal phase, and an XIn oxide crystal phase, and
a constitution of the ZnIn oxide crystal phase is Zn₃In₂O₆ and/or Zn₄In₂O₇.

11. An oxide sintered body for forming an oxide semiconductor film for use in a thin film transistor, the oxide sintered body comprising, as metal elements:
In and Zn; and
an element X, being either of La and Nd,
wherein
contents of the In and the Zn in total metal elements are:
In: greater than or equal to 30 atm % and less than or equal to 90 atm %; and
Zn: greater than or equal to 9 atm % and less than or equal to 70 atm %,
the oxide sintered body comprises an In oxide crystal phase, a ZnIn oxide crystal phase, and an XIn oxide crystal phase, and
a constitution of the ZnIn oxide crystal phase is Zn₃In₂O₆ and/or Zn₄In₂O₇.
